(19) United States
(12) Patent Application Publication
(10) Pub. No.: US 2007/0257282 A1
(43) Pub. Date: Nov. 8, 2007

(54) Image Sensor Applying Power Voltage to Backside of Semiconductor Substrate and Method of Manufacturing Image Sensor

(75) Inventors: Yo-han Sun, Suwon-si (KR); Jong-jin Lee, Seoul (KR); Bum-suk Kim, Seoul (KR); Yun-ho Jang, Seoul (KR); Sae-young Kim, Suwon-si (KR); Keun-chan Yuk, Seoul (KR); Getman Alexander, Yongin-si (KR)

Correspondence Address: F. CHAU & ASSOCIATES, LLC, 130 WOODBURY ROAD, WOODBURY, NY, 11797, US

(73) Assignee: Samsung Electronics Co, Ltd., Suwon-si (KR)

(21) Appl. No.: 11/672,866

(22) Filed: Feb. 8, 2007

(30) Foreign Application Priority Data
Feb. 8, 2006 (KR) 10-2006-0012044

(51) Int. Cl. H01L 27/148; H01L 21/339

(52) U.S. Cl. 257/229; 438/60; 257/E27.151; 257/E21.457

(57) ABSTRACT

An image sensor applying a power voltage to a backside of a semiconductor substrate includes a first type semiconductor substrate, a first type semiconductor layer formed on the first type semiconductor substrate, a second type semiconductor layer formed on the first type semiconductor layer, and a power voltage receiver formed on a backside of the first type semiconductor substrate opposite the first type semiconductor layer with respect to the first type semiconductor substrate, wherein the power voltage receiver receives a power voltage from outside and applies the power voltage to the first type semiconductor substrate.

### CROSS-REFERENCE TO RELATED APPLICATION

This application claims the priority of Korean Patent Application No. 10-2006-0012044, filed on 8 Feb. 2006, in the Korean Intellectual Property Office, the disclosure of which is herein incorporated by reference in its entirety.

### BACKGROUND OF THE INVENTION

1. Field of the Invention

The present invention relates to an image sensor, and more particularly to an image sensor for applying a power voltage to the backside of a semiconductor substrate.

2. Description of Related Art

Image sensors are photoelectric transducers that sense light and transduce the light into an electrical signal. Typically, image sensors comprise a plurality of pixels disposed on a semiconductor substrate in a matrix pattern. Each pixel comprises photodiode and transistors. A semiconductor layer and photodiode disposed on the semiconductor substrate may detect light and generate photo-charges. The photo-charges move to the photodiode. Transistors output electric signals according to the number of photo-charges.

Image sensors may cause cross-talk in which the photo-charges generated on the semiconductor layer of the semiconductor substrate do not move to the photodiode of a corresponding pixel but move to photodiodes of neighboring pixels.

As image sensors having high integration are developed, distances between pixels are become shorter, and the size of photodiode smaller. As integration increases, the possibility that photo-charges generated on the semiconductor layer of the semiconductor substrate move to photodiodes of the neighboring pixels increases, increasing cross-talk.

### SUMMARY OF THE INVENTION

According to an exemplary embodiment of the present invention, there is provided an image sensor comprising a first type semiconductor substrate, a first type semiconductor layer formed on the first type semiconductor substrate, a second type semiconductor layer formed on the first type semiconductor layer, and a power voltage receiver formed on a backside of the first type semiconductor substrate opposite the first type semiconductor layer with respect to the first type semiconductor substrate, wherein the power voltage receiver receives a power voltage from outside and applies the power voltage to the first type semiconductor substrate.

According to another exemplary embodiment of the present invention, there is provided a method of manufacturing an image sensor, comprising grinding a backside of a semiconductor substrate, and forming a power voltage receiver on the backside of the semiconductor substrate, wherein the power voltage receiver receives a power voltage and applies the power voltage to the semiconductor substrate.

### BRIEF DESCRIPTION OF THE DRAWING

The present invention will become more apparent by describing in detail exemplary embodiments thereof with reference to the attached drawings in which:

FIG. 1 is a cross-sectional view illustrating an image sensor applying a power voltage to the backside of a semiconductor substrate according to an embodiment of the present invention;

FIG. 2A is a cross-sectional view illustrating a power voltage receiver according to an embodiment of the present invention;

FIG. 2B is a bottom view illustrating the power voltage receiver illustrated in FIG. 2A;

FIG. 3 is a cross-sectional view illustrating a power voltage receiver according to another embodiment of the present invention;

FIG. 4 is a graph illustrating an electric potential formed in a dotted line A-B of the image sensor illustrated in FIG. 1;

FIG. 5 is a flowchart illustrating a method of manufacturing an image sensor including the power voltage receiver illustrated in FIGS. 2A and 2B according to an embodiment of the present invention; and

FIG. 6 is a flowchart illustrating a method of manufacturing an image sensor including the power voltage receiver illustrated in FIG. 3 according to another embodiment of the present invention.

### DETAILED DESCRIPTION OF PREFERRED EMBODIMENTS

The present invention will now be described more fully with reference to the accompanying drawings, in which exemplary embodiments of the invention are shown. Like reference numerals in the drawings denote like elements.

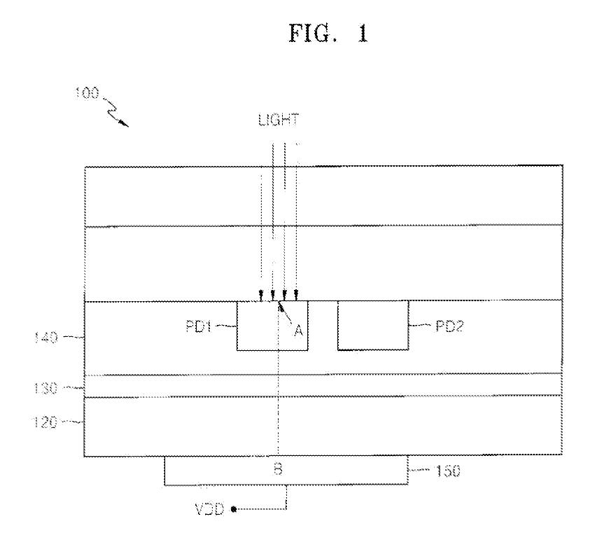

FIG. 1 is a cross-sectional view illustrating an image sensor 100 applying a power voltage to a backside of a semiconductor substrate according to an embodiment of the present invention. Referring to FIG. 1, the image sensor 100 includes a first type semiconductor substrate 120, a first type semiconductor layer 130, a second type semiconductor layer 140, and a power voltage receiver 150. The image sensor 100 can comprise photodiodes PD1 and PD2. The photodiodes PD1 and PD2 receive light and generate photo-charges according to the amount of light.

The first type semiconductor layer 130 may be formed on the first type semiconductor substrate 120. The second type semiconductor layer 140 may be formed on the first type semiconductor layer 130.

The first type semiconductor substrate 120 can be an N type semiconductor substrate. The first type semiconductor layer 130 can be an N+ type semiconductor layer. The second type semiconductor layer 140 can be a P type semiconductor layer. The first type semiconductor layer 130 has a predetermined thickness from the surface of the first type semiconductor substrate 120. The predetermined thickness may be more than about 0.5 μm.

A power voltage receiver 150 is formed on the backside of the first type semiconductor substrate 120, opposite the first type semiconductor layer 130 with respect to the first type semiconductor substrate 120. The power voltage receiver 150 receives a power voltage VDD and applies the power voltage VDD to the first type semiconductor substrate 120.

The image sensor 100 can be a CMOS image sensor.

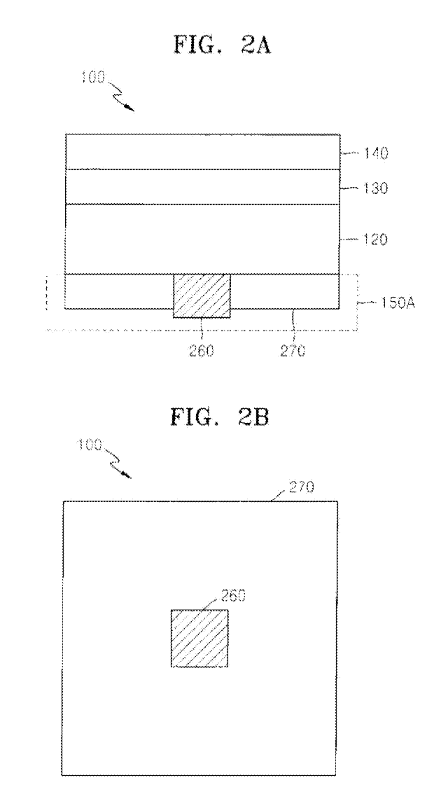

FIG. 2A is a cross-sectional view illustrating a power voltage receiver 150A according to an embodiment of the present invention. Referring to FIG. 2A, the power voltage receiver 150A includes a metal pad 260. The metal pad 260 receives the power voltage VDD, and applies the power voltage VDD to the first type semiconductor substrate 120. The power voltage receiver 150A may further include an insulation layer 270 formed around the metal pad 260. The metal pad 260 can be formed of aluminum. The insulation layer 270 can be formed of oxide.

FIG. 2B is a bottom view illustrating the power voltage receiver 150A illustrated in FIG. 2A. Referring to FIG. 2B the insulation layer 270 may be formed around the metal pad 260.

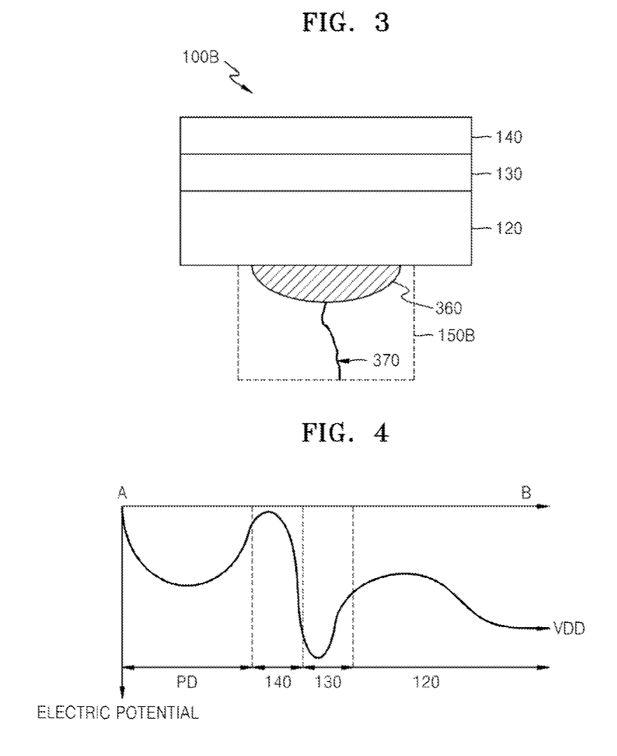

FIG. 3 is a cross-sectional view illustrating a power voltage receiver 150B according to another embodiment of the present invention. Referring to FIG. 3 the power voltage receiver 150B of the present embodiment includes a conducting paste 360. The power voltage receiver 150B can further include a transmission line 370 connected to the conducting paste 360. The power voltage VDD is applied to the first type semiconductor substrate 120 via the conducting paste 360 and the transmission line 370.

The operation of the image sensor 100 will now be described.

When the image sensor 100 operates, the power voltage VDD is applied to the N type semiconductor substrate 120 through the power voltage receiver 150. In this case, photo-charges generated on the N+ type semiconductor layer 130 or the P type semiconductor layer 140 move to the power voltage VDD through the first type semiconductor substrate 120. The image sensor 100 reduces cross-talk since the photo-charges, which typically cause cross-talk generated on the P type semiconductor layer 140 do not move to photodiodes of neighboring pixels.

FIG. 4 is a graph illustrating an electric potential formed in a line A-B of the image sensor 100 illustrated in FIG. 1. Referring to FIG. 4, the electric potential is formed if the power voltage VDD is applied to the N type semiconductor substrate 120 through the power voltage receiver 150.

Photo-charges generated on the P type semiconductor layer 140 move to the N+ type semiconductor layer 130 due to a difference in electric potential between the N+ type semiconductor layer 130 and the P type semiconductor layer 140. The photo-charges accumulated on the N+ type semiconductor layer 130 move to the N type semiconductor substrate 120 to which the power voltage VDD is applied.

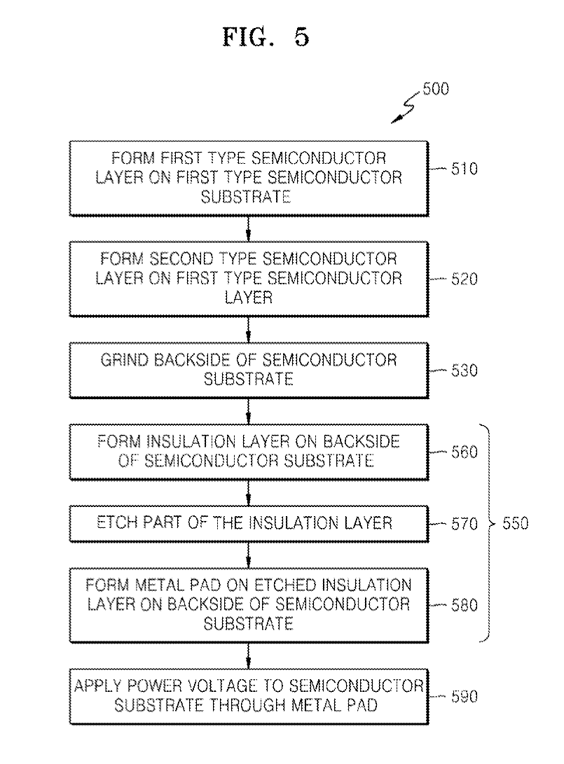

FIG. 5 is a flowchart illustrating a method 500 of manufacturing an image sensor including the power voltage receiver 150A illustrated in FIGS. 2A and 2B according to an embodiment of the present invention. Referring to FIG. 5, the method 500 of manufacturing the image sensor comprises grinding the backside of a semiconductor substrate (block 530) and forming a power voltage receiver on the backside of the semiconductor substrate (block 550). The power voltage receiver is formed to receive a power voltage from outside the image sensor and apply the power voltage to the semiconductor substrate.

The forming of the power voltage receiver comprises forming an insulation layer on the backside of the semiconductor substrate (block 560), etching a part of the insulation layer (block 570), and forming a metal pad on the backside of the semiconductor substrate (block 580). In block 580, the metal pad is formed on the etched insulation layer.

The method 500 of manufacturing the image sensor according to an exemplary embodiment of the present embodiment further comprises forming a first type semiconductor layer on a first type semiconductor substrate (block 510), and forming a second type semiconductor layer on the first type semiconductor layer (block 520). The first type semiconductor substrate can be an N type semiconductor substrate. The first type semiconductor layer can be an N+ type semiconductor layer. The second type semiconductor layer can be a P type semiconductor layer.

The N type material is doped on the N type semiconductor substrate so that the N type semiconductor layer is formed on the N type semiconductor substrate in block 510. The N type semiconductor layer has a predetermined thickness from the surface of the N type semiconductor substrate. The predetermined thickness may be more than about 0.5 μm. The P type semiconductor layer is formed on the N+ type semiconductor layer in block 520. If the depth of the N+ type semiconductor layer is more than about 0.5 μm, the P type semiconductor layer may be formed on the N+ type semiconductor layer.

Thereafter, the backside of the semiconductor substrate is grinded in block 530, the insulation layer is formed on the backside of the semiconductor substrate in block 560, a part of the insulation layer is etched in block 570, and the metal pad is formed on the etched insulation layer of the backside of the semiconductor substrate in block 580.

When the image sensor operates, the power voltage is applied to the semiconductor substrate through the metal pad in block 590.

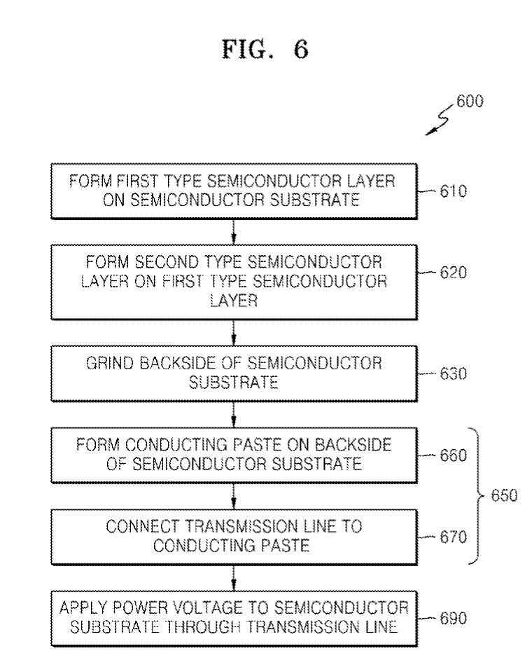

FIG. 6 is a flowchart illustrating a method 600 of manufacturing an image sensor including the power voltage receiver 1508 illustrated in FIG. 3 according to another embodiment of the present invention. Referring to FIG. 6, the method 600 of manufacturing the image sensor comprises grinding the backside of a semiconductor substrate (block 630) and forming a power voltage receiver on the backside of the semiconductor substrate (block 650). The power voltage receiver is formed to receive a power voltage from outside the image sensor and apply the power voltage to the semiconductor substrate.

The forming of the power voltage receiver comprises depositing a conducting paste on the backside of the semiconductor substrate (block 660), and connecting a transmission line to the conducting paste (block 670).

The method 600 of manufacturing the image sensor is substantially the same as the method 500 of manufacturing the image sensor except blocks 660 and 670. Thus, the detailed description of method 600 of manufacturing the image sensor is omitted.

An image sensor and a method of manufacturing the image sensor according to an embodiment of the present invention apply a power voltage to the backside of a semiconductor substrate, thereby substantially avoiding cross-talk between pixels.

While the present invention has been particularly shown and described with reference to exemplary embodiments thereof, it will be understood by those skilled in the art that various changes in form and details may be made therein without departing from the spirit and scope of the disclosure. Exemplary embodiments should be considered in a descriptive sense only and not for purposes of limitation.

What is claimed is:

1. An image sensor comprising:
a first type semiconductor substrate;
a first type semiconductor layer formed on the first type semiconductor substrate;
a second type semiconductor layer formed on the first type semiconductor layer; and
a power voltage receiver formed on a backside of the first type semiconductor substrate opposite the first type semiconductor layer with respect to the first type semiconductor substrate,
wherein the power voltage receiver receives a power voltage and applies the power voltage to the first type semiconductor substrate.

2. The image sensor of claim 1, wherein the power voltage receiver comprises a metal pad receiving the power voltage and applying the power voltage to the first type semiconductor substrate.

3. The image sensor of claim 2 wherein the power voltage receiver further comprises an insulation layer formed around the metal pad.

4. The image sensor of claim 3, wherein the metal pad is formed of aluminum, and the insulation layer is formed of oxide.

5. The image sensor of claim 1, wherein the power voltage receiver further comprises conducting paste.

6. The image sensor of claim 5, wherein the power voltage receiver further comprises a transmission line connected to the conducting paste

7. The image sensor of claim 1, wherein the first type semiconductor substrate is an N type semiconductor substrate, the first type semiconductor layer is an N+ type semiconductor layer, and the second type semiconductor layer is a P type semiconductor layer.

8. The image sensor of claim 1, wherein the first type semiconductor layer has a predetermined thickness from the surface of the first type semiconductor substrate.

9. The image sensor of claim 8, wherein the predetermined thickness is more than about 0.5 μm.

10. The image sensor of claim 1, wherein the image sensor is a CMOS image sensor.

11. A method of manufacturing an image sensor, comprising:
grinding a backside of a semiconductor substrate; and
forming a power voltage receiver on the backside of the semiconductor substrate,
wherein the power voltage receiver receives a power voltage and applies the power voltage to the semiconductor substrate.

12. The method of claim 11, wherein the forming of the power voltage receiver comprises forming a metal pad on the backside of the semiconductor substrate,
wherein the metal pad receives the power voltage and applies the power voltage to the semiconductor substrate.

13. The method of claim 12, further comprising:
forming an insulation layer on the backside of the semiconductor substrate; and
etching a part of the insulation layer,
wherein the metal pad is formed on the etched insulation layer.

14. The method of claim 13, wherein the metal pad is formed of aluminum, and the insulation layer is formed of oxide.

15. The method of claim 11, wherein the forming of the power voltage receiver comprises: depositing a conducting paste on the backside of the semiconductor substrate.

16. The method of claim 15, wherein the forming of the power voltage receiver further comprises: connecting a transmission line to the conducting paste.

17. The method of claim 11, further comprising:
forming a first type semiconductor layer on a first type semiconductor substrate; and
forming a second type semiconductor layer on the first type semiconductor layer.

18. The method of claim 17, wherein the forming of the first type semiconductor layer comprises: doping the first type semiconductor substrate with a first type material, and forming the first type semiconductor layer on the first type semiconductor substrate.

19. The method of claim 17, wherein the first type semiconductor substrate is an N type semiconductor substrate, the first type semiconductor layer is an N+ type semiconductor substrate, and the second type semiconductor layer is a P type semiconductor substrate.

20. The method of claim 17, wherein the first type semiconductor layer has a predetermined thickness from the surface of the first type semiconductor substrate.

21. The method of claim 20, wherein the predetermined thickness is more than about 0.5 μm.

22. The method of claim 11 wherein the image sensor is a CMOS image sensor.
